(19) United States
(12) Patent Application Publication
(10) Pub. No.: US 2026/0155339 A1
(43) Pub. Date: Jun. 4, 2026

(54) SUBSTRATE PROCESSING APPARATUS

(71) Applicant: Tokyo Electron Limited, Tokyo (JP)

(72) Inventors: Kyosuke ABE, Miyagi (JP); Masahiro SUZUKI, Miyagi (JP)

(73) Assignee: Tokyo Electron Limited, Tokyo (JP)

(21) Appl. No.: 19/454,563

(22) Filed: Jan. 21, 2026

Related U.S. Application Data
(63) Continuation of application No. PCT/JP2024/025979, filed on Jul. 19, 2024.

(30) Foreign Application Priority Data
Jul. 28, 2023 (JP) 2023-123714

(51) Int. Cl. H01J 37/32

(52) U.S. Cl. CPC H01J 37/32642; H01J 37/32715; H01J 2237/2007; H01J 2237/334

(57) ABSTRACT

A substrate processing apparatus includes an electrostatic chuck having a substrate support surface and a ring support surface, the ring support surface including a first through-hole through which a lift pin is to be inserted into the ring support surface; an edge ring supported by the ring support surface; and a cylindrical member inserted into the first through-hole of the electrostatic chuck, the cylindrical member including a second through-hole. The cylindrical member includes a first shaft portion inserted into the first through-hole of the electrostatic chuck; and a first head portion arranged on the ring support surface of the electrostatic chuck when the first shaft portion is inserted into the first through-hole of the electrostatic chuck. The edge ring includes a first groove in which the first head portion is to be arranged, the first groove being provided on a lower surface of the edge ring.

### CROSS-REFERENCE TO RELATED APPLICATIONS

This application is a continuation application of International Application No. PCT/JP2024/025979, filed on Jul. 19, 2024, and designating the U.S., which is based upon and claims priority to Japanese Patent Application No. 2023-123714, filed on Jul. 28, 2023, the entire contents of each are incorporated herein by reference.

### BACKGROUND

### 1. Technical Field

The present disclosure relates to a substrate processing apparatus.

### 2. Description of the Related Art

Patent Document 1 discloses an apparatus for processing a substrate, including a substrate support; an electrostatic chuck disposed on the substrate support and including a first portion, a second portion, and a third portion; and a processing kit surrounding the electrostatic chuck, the processing kit including a support ring disposed on a surface of the third portion of the electrostatic chuck; an edge ring disposed on a surface of the second portion of the electrostatic chuck and movable independently of the support ring; and a cover ring disposed on the support ring and having a first surface that is in contact with the support ring.

### RELATED ART DOCUMENT

### Patent Document

Patent Document 1: Japanese National Publication of International Patent Application No. 2019-505088

### SUMMARY

According to one embodiment of the present disclosure, a substrate processing apparatus includes an electrostatic chuck having a substrate support surface and a ring support surface, the ring support surface including a first through-hole through which a lift pin is to be inserted into the ring support surface; an edge ring supported by the ring support surface; and a cylindrical member inserted into the first through-hole of the electrostatic chuck, the cylindrical member including a second through-hole. The cylindrical member includes a first shaft portion inserted into the first through-hole of the electrostatic chuck; and a first head portion arranged on the ring support surface of the electrostatic chuck when the first shaft portion is inserted into the first through-hole of the electrostatic chuck. The edge ring includes a first groove in which the first head portion is to be arranged, the first groove being provided on a lower surface of the edge ring.

### BRIEF DESCRIPTION OF THE DRAWINGS

FIG. 1 is an example of a diagram for explaining a configuration example of a plasma processing system;

FIG. 2 is an example of a diagram for explaining a configuration example of an inductively coupled plasma processing apparatus;

FIG. 3 is an example of one enlarged cross-sectional view of a substrate support according to a first embodiment;

FIG. 4 is an example of another enlarged cross-sectional view of the substrate support according to the first embodiment;

FIG. 5 is a diagram of the substrate support viewed from above;

FIG. 6A is an example of a perspective view for explaining an alignment structure of an under ring;

FIG. 6B is an example of a perspective view illustrating the alignment structure of the under ring;

FIG. 6C is an example of a perspective view illustrating the alignment structure of the under ring;

FIG. 7A is an example of a schematic view illustrating the alignment structure of the under ring;

FIG. 7B is an example of a schematic view illustrating the alignment structure of the under ring;

FIG. 8A is an example of a perspective view illustrating an alignment structure of an inner ring;

FIG. 8B is an example of a perspective view illustrating the alignment structure of the inner ring;

FIG. 8C is an example of a perspective view illustrating the alignment structure of the inner ring;

FIG. 9A is an example of a schematic view illustrating the alignment structure of the inner ring;

FIG. 9B is an example of a schematic view illustrating the alignment structure of the inner ring;

FIG. 10 is an example of an enlarged cross-sectional view of a substrate support according to a second embodiment;

FIG. 11A is an example of a diagram for explaining an alignment structure of an inner ring;

FIG. 11B is an example of a diagram for explaining the alignment structure of the inner ring;

FIG. 11C is an example of a diagram for explaining the alignment structure of the inner ring;

FIG. 11D is an example of a diagram for explaining the alignment structure of the inner ring;

FIG. 12A is another example of a diagram for explaining the alignment structure of the inner ring; and

FIG. 12B is another example of a diagram for explaining the alignment structure of the inner ring.

### DETAILED DESCRIPTION

Hereinafter, various exemplary embodiments will be described in detail with reference to the drawings. Here, in each of the drawings, the same reference numerals denote the same or corresponding parts.

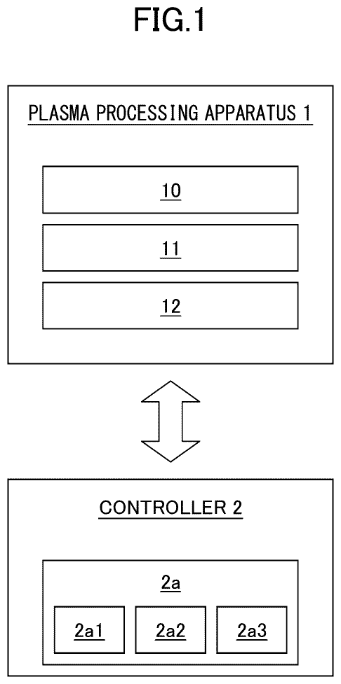

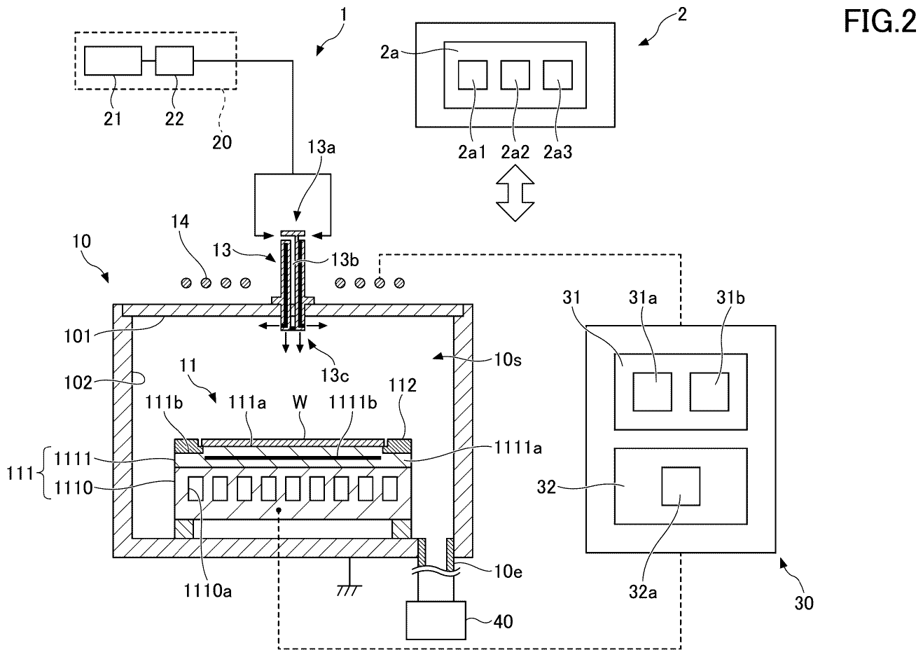

FIG. 1 is an example of a diagram for explaining a configuration example of a plasma processing system. In one embodiment, the plasma processing system includes a plasma processing apparatus (a substrate processing apparatus) 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Additionally, the plasma processing chamber 10 includes at least one gas supply port for supplying at least one processing gas into the plasma processing space, and at least one gas discharge port for discharging the gas from the plasma processing space. The gas supply port is connected to a gas supply 20 (see FIG. 2) described later, and the gas discharge port is connected to an exhaust system 40 (see FIG. 2) described later. The substrate support 11 is disposed within the plasma processing space and has a substrate support surface for supporting a substrate.

The plasma generator 12 is configured to generate plasma from at least one processing gas supplied into the plasma processing space. The plasma formed in the plasma processing space may be a capacitively coupled plasma (CCP), an inductively coupled plasma (ICP), an electron-cyclotron-resonance (ECR) plasma, a helicon wave plasma (HWP), a surface wave plasma (SWP), or the like. Additionally, various types of plasma generators may be used, including an alternating current (AC) plasma generator and a direct current (DC) plasma generator. In one embodiment, the AC signal (AC power) used in the AC plasma generator has a frequency in the range of 100 kHz to 10 GHz. The AC signal includes a radio frequency (RF) signal and a microwave signal. In one embodiment, the RF signal has a frequency in the range of 100 kHz to 150 MHz.

The controller 2 processes computer-executable instructions that cause the plasma processing apparatus 1 to perform the various steps described in the present disclosure. The controller 2 may be configured to control the elements of the plasma processing apparatus 1 to perform the various steps described herein. In one embodiment, all or a portion of the controller 2 may be included in the plasma processing apparatus 1. The controller 2 may include a processor 2a1, a storage unit 2a2, and a communication interface 2a3. The controller 2 may be implemented by a computer 2a, for example. The processor 2a1 may be configured to perform various control operations by reading a program from the storage unit 2a2 and executing the read program. This program may be stored in advance in the storage unit 2a2 or may be acquired via a medium when necessary. The acquired program is stored in the storage unit 2a2, read from the storage unit 2a2 by the processor 2a1, and executed. The medium may be any storage medium readable by the computer 2a or a communication line connected to the communication interface 2a3. The processor 2a1 may be a central processing unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

A configuration example of an inductively coupled plasma processing apparatus, which is an example of the plasma processing apparatus 1, will be described below. FIG. 2 is an example of a diagram for explaining the configuration example of the inductively coupled plasma processing apparatus.

The inductively coupled plasma processing apparatus 1 includes the plasma processing chamber 10, the gas supply 20, a power supply 30, and the exhaust system 40. The plasma processing chamber 10 includes a dielectric window 101. Additionally, the plasma processing apparatus 1 includes a substrate support 11, a gas introduction section, and an antenna 14. The substrate support 11 is disposed within the plasma processing chamber 10. The antenna 14 is disposed on or above the plasma processing chamber 10 (i.e., on or above the dielectric window 101). The plasma processing chamber 10 has a plasma processing space 10s defined by the dielectric window 101, side walls 102 of the plasma processing chamber 10, and the substrate support 11. The plasma processing chamber 10 is grounded.

The substrate support 11 includes a body 111 and a ring assembly 112. The body 111 includes a central region 111a for supporting a substrate W and an annular region 111b for supporting the ring assembly 112. A wafer is an example of the substrate W. The annular region 111b of the body 111 surrounds the central region 111a of the body 111 in plan view. The substrate W is disposed on the central region 111a of the body 111 and the ring assembly 112 is disposed on the annular region 111b of the body 111 to surround the substrate W on the central region 111a of the body 111. Thus, the central region 111a is also referred to as a substrate support surface for supporting the substrate W and the annular region 111b is also referred to as a ring support surface for supporting the ring assembly 112.

In one embodiment, the body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a and an electrostatic electrode 1111b disposed within the ceramic member 1111a. The ceramic member 1111a includes the central region 111a. In one embodiment, the ceramic member 1111a also includes the annular region 111b. Here, another member surrounding the electrostatic chuck 1111, such as an annular electrostatic chuck or an annular insulating member, may include the annular region 111b. In this case, the ring assembly 112 may be disposed on the annular electrostatic chuck or the annular insulating member, or on both the electrostatic chuck 1111 and the annular insulating member. Additionally, at least one RF/DC electrode coupled to a RF power supply 31, a DC power supply 32, or both described later may be disposed within the ceramic member 1111a. In this case, at least one RF/DC electrode functions as a bias electrode. Here, the conductive member of the base 1110 and at least one RF/DC electrode may function as a plurality of bias electrodes. Additionally, the electrostatic electrode 1111b may function as a bias electrode. Thus, the substrate support 11 includes at least one bias electrode.

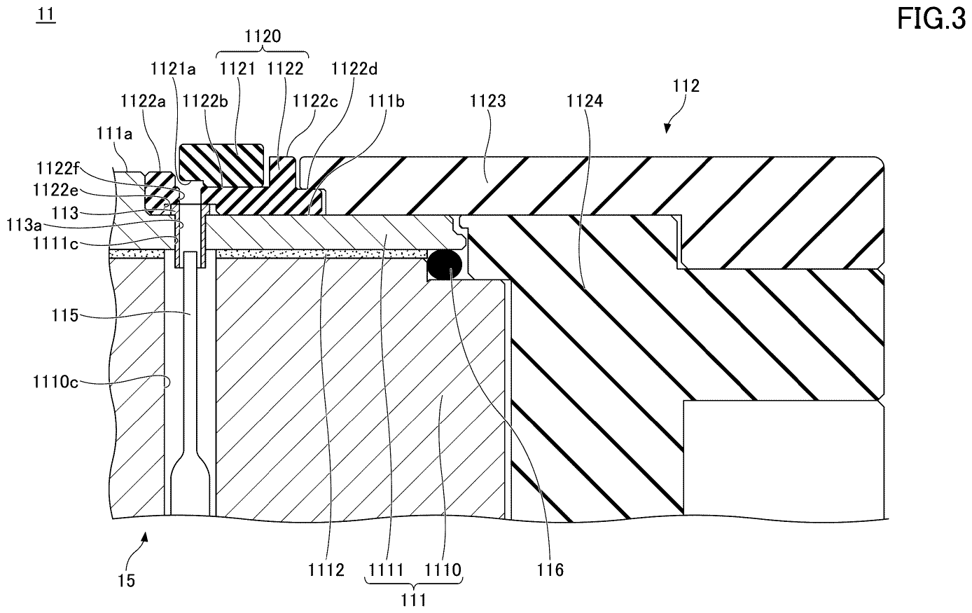

The ring assembly 112 includes one or more annular members. In one embodiment, the one or more annular members include one or more edge rings 1120 (see FIG. 3, for example) and at least one cover ring 1123 (see FIG. 3, for example). The one or more edge rings 1120 are formed of a conductive or insulating material and the cover ring 1123 is formed of an insulating material.

Additionally, the substrate support 11 may include a temperature control module configured to adjust, to a target temperature, at least one of the electrostatic chuck 1111, the ring assembly 112, or the substrate W. The temperature control module may include a heater, a heat transfer medium, a flow channel 1110a, or a combination thereof. A heat transfer fluid, such as brine or gas, flows through the flow channel 1110a. In one embodiment, the flow channel 1110a is formed in the base 1110 and one or more heaters are disposed within the ceramic member 1111a of the electrostatic chuck 1111. Additionally, the substrate support 11 may include a heat transfer gas supply configured to supply heat transfer gas to a gap between a back surface of the substrate W and the central region 111a.

The gas introduction section is configured to introduce at least one processing gas from the gas supply 20 into the plasma processing space 10s. In one embodiment, the gas introduction section includes a center gas injector (CGI) 13. The center gas injector 13 is disposed above the substrate support 11 and is attached to a central opening formed in the dielectric window 101. The center gas injector 13 includes at least one gas supply port 13a, at least one gas flow channel 13b, and at least one gas introduction port 13c. The processing gas supplied to the gas supply port 13a passes through the gas flow channel 13b and is introduced into the plasma processing space 10s through the gas introduction port 13c. In addition to or instead of the center gas injector 13, the gas introduction section may include one or more side gas injectors (SGI) attached to one or more openings formed in the side wall 102.

The gas supply 20 may include at least one gas source 21 and at least one flow controller 22. In one embodiment, the gas supply 20 is configured to supply at least one processing gas to the gas introduction section from a corresponding gas source 21 via a corresponding flow controller 22. The at least one flow controller 22 may include, for example, a mass flow controller or a pressure-controlled flow controller. Further, the gas supply 20 may include at least one flow modulation device configured to modulate or pulse the flow rate of the at least one processing gas.

The power supply 30 includes the RF power supply 31 coupled to the plasma processing chamber 10 via at least one impedance matching circuit. The RF power supply 31 is configured to provide at least one RF signal (RF power) to at least one bias electrode and the antenna 14. With this configuration, plasma is formed from the at least one processing gas supplied into the plasma processing space 10s. Thus, the RF power supply 31 may function as at least part of the plasma generator 12. Additionally, by providing the bias RF signal to the at least one bias electrode, a bias potential is generated in the substrate W, and ions in the formed plasma can be drawn into the substrate W.

In one embodiment, RF power supply 31 includes a first RF generator 31a and a second RF generator 31b. The first RF generator 31a is coupled to the antenna 14 via at least one impedance matching circuit and is configured to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The one or more generated source RF signals are supplied to the antenna 14.

The second RF generator 31b is coupled to at least one bias electrode via at least one impedance matching circuit and configured to generate a bias RF signal (bias RF power). The frequency of the bias RF signal may be equal to or different from the frequency of the source RF signal. In one embodiment, the bias RF signal has a frequency lower than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The one or more generated bias RF signals are supplied to at least one bias electrode. Additionally, in various embodiments, at least one of the source RF signal or the bias RF signal may be pulsed.

Additionally, the power supply 30 may include the DC power supply 32 coupled to the plasma processing chamber 10. The DC power supply 32 includes a bias DC generator 32a. In one embodiment, the bias DC generator 32a is coupled to at least one bias electrode and is configured to generate a bias DC signal. The generated bias DC signal is applied to at least one bias electrode.

In various embodiments, the bias DC signal may be pulsed. In this case, a sequence of voltage pulses is applied to at least one bias electrode. The voltage pulses may have a pulse waveform that is rectangular, trapezoidal, triangular, or combinations thereof. In one embodiment, a waveform generator for generating a sequence of voltage pulses from the DC signal is coupled between the bias DC generator 32a and at least one bias electrode. Thus, the bias DC generator 32a and the waveform generator constitute a voltage pulse generator. The voltage pulses may have positive polarity or negative polarity. Additionally, the sequence of voltage pulses may include one or more positive polarity voltage pulses and one or more negative polarity voltage pulses within one period. Here, the bias DC generator 32a may be provided in addition to the RF power supply 31 or may be provided instead of the second RF generator 31b.

The antenna 14 includes one or more coils. In one embodiment, the antenna 14 may include an outer coil and an inner coil that are coaxially arranged. In this case, the RF power supply 31 may be coupled to both the outer coil and the inner coil, or to either the outer coil or the inner coil. In the former case, the same RF generator may be coupled to both the outer coil and the inner coil, or different RF generators may be coupled to the outer coil and the inner coil separately.

The exhaust system 40 may be connected, for example, to a gas discharge port 10e provided at the bottom of the plasma processing chamber 10. The exhaust system 40 may include a pressure regulating valve and a vacuum pump. The pressure in plasma processing space 10s is regulated by the pressure regulating valve. The vacuum pump may include a turbomolecular pump, a dry pump, or a combination thereof.

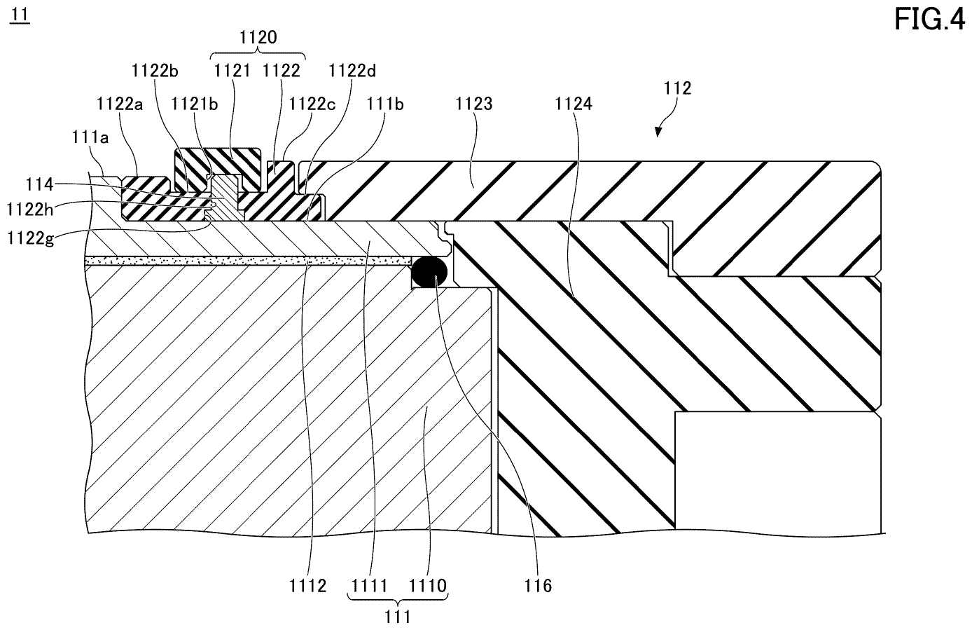

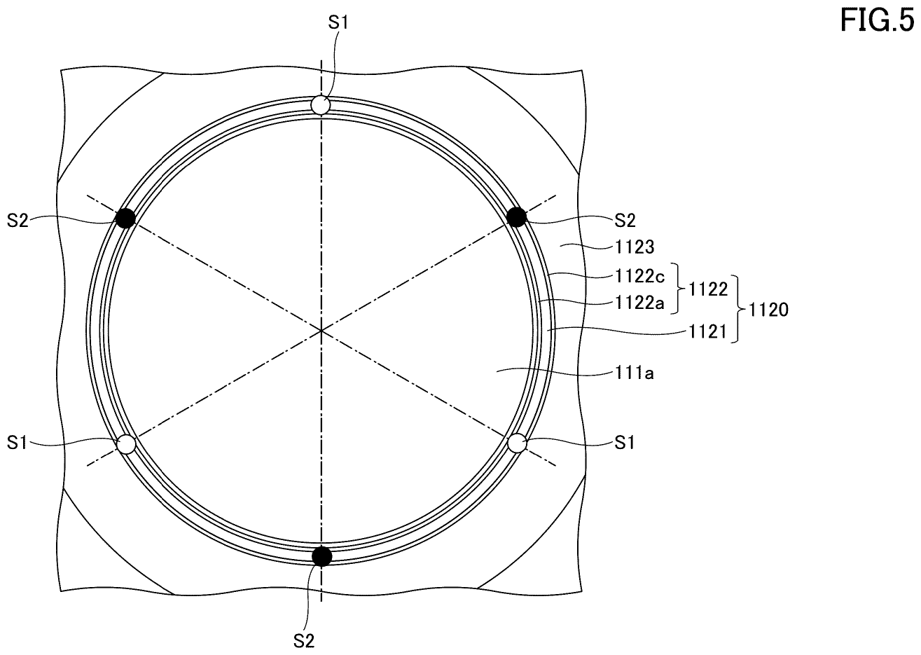

Next, the substrate support 11 according to a first embodiment will be further described with reference to FIGS. 3 to 5. FIG. 3 is an example of one enlarged cross-sectional view of the substrate support 11 according to the first embodiment. FIG. 4 is an example of another enlarged cross-sectional view of the substrate support 11 according to the first embodiment. FIG. 5 is a view of the substrate support 11 viewed from above. Here, FIGS. 3 and 4 are cross-sectional views taken by cutting the substrate support 11 in the radial direction, the left side of the drawing corresponds to the center side of the substrate support 11, and the right side of the drawing corresponds to the outer periphery side of the substrate support 11. Additionally, FIG. 3 is a cross-sectional view at a position S1 (a position indicated by a hollow circle in FIG. 5) where an alignment structure for an under ring 1122 described later is provided. Additionally, FIG. 4 is a cross-sectional view at a position S2 (a position indicated by a solid circle in FIG. 5) where an alignment structure for an inner ring 1121 described later is provided.

As illustrated in FIGS. 3 and 4, the body 111 of the substrate support 11 includes the base 1110 and the electrostatic chuck 1111. The electrostatic chuck 1111 is disposed on the base 1110 via an adhesive layer 1112. The adhesive layer 1112 is disposed between the base 1110 and the electrostatic chuck 1111, and adheres the upper surface of the base 1110 to the lower surface of the electrostatic chuck 1111. A seal member 116 is formed of a material having corrosion resistance, plasma resistance, and heat resistance, and protects the adhesive layer 1112 from the processing gas, the plasma, and the like in the plasma processing space 10s.

Additionally, as illustrated in FIG. 3, the substrate support 11 includes a height adjusting mechanism 15 configured to adjust the height of the inner ring 1121 described later. The height adjusting mechanism 15 includes a raising and lowering mechanism (not illustrated) configured to raise and lower a lift pin 115 arranged in a through-hole 1110c of the base 1110. The height adjusting mechanism 15 lifts the inner ring 1121 disposed on a support 1122b, described later, by raising the lift pin 115 above the upper surface of the support 1122b, thereby adjusting the height of the inner ring 1121. Additionally, the height adjusting mechanism 15 places the inner ring 1121 on the support 1122b by lowering the lift pin 115 below the upper surface of the support 1122b.

The height adjusting mechanism 15 adjusts, when the inner ring 1121 is worn down from the upper surface due to plasma processing (for example, etching processing), the height of the upper surface of the inner ring 1121 in accordance with the amount of wear. This allows the height of the sheath on the inner ring 1121 to be corrected, thereby securing uniformity of plasma processing. Additionally, the frequency of replacement of the inner ring 1121 can be reduced. The height adjusting mechanism 15 adjusts the height of the inner ring 1121 to correct the height of the sheath on the inner ring 1121. Accordingly, the incident angle of ions on the outer periphery of the substrate W can be adjusted. The height adjusting mechanism 15 can deliver the inner ring 1121 to a transfer device (not illustrated) by, for example, raising and lowering the lift pin 115. Accordingly, the worn-down inner ring 1121 can be carried out from the plasma processing chamber 10. Additionally, the height adjusting mechanism 15 receives a new inner ring 1121 delivered by the transfer device (not illustrated) by, for example, raising and lowering the lift pin 115 and places it on the under ring 1122. As described, the inner ring 1121 can be replaced without opening the plasma processing chamber 10 to the atmosphere.

As illustrated in FIGS. 3 to 5, the ring assembly 112 includes an edge ring 1120, a cover ring 1123, and an insulator ring 1124.

The edge ring 1120 includes an inner ring (a first annular member) 1121 and an under ring (a second annular member) 1122. The inner ring 1121 and the under ring 1122 are formed of a material selected from SiC, Si, and SiO₂, for example.

The inner ring 1121 is an annular member and is disposed on the support 1122b of the under ring 1122 so as to surround the substrate W disposed on the central region 111a (the substrate support surface) of the body 111.

The under ring 1122 is an annular member and is disposed on the annular region 111b (the ring support surface) of the body 111. The under ring 1122 includes an inner circumferential portion 1122a, a support 1122b, an outer circumferential portion 1122c, and a flange 1122d in order from the inner side in the radial direction, and the heights of the upper surfaces thereof are different from each other.

The inner circumferential portion 1122a is a portion disposed below the substrate W supported on the central region 111a of the body 111. The upper surface of the inner circumferential portion 1122a is formed at a position slightly lower than or at the same height as the substrate support surface (the central region 111a) of the electrostatic chuck 1111.

The support 1122b is provided on the outer peripheral side of the inner circumferential portion 1122a, and the inner ring 1121 is disposed on the support 1122b. The upper surface of the support 1122b is formed at a lower position than the upper surface of the inner circumferential portion 1122a.

The outer circumferential portion 1122c is provided on the outer peripheral side of the support 1122b. The upper surface of the outer circumferential portion 1122c is formed at a higher position than the upper surface of the inner circumferential portion 1122a and the upper surface of the support 1122b. Additionally, the upper surface of the outer circumferential portion 1122c is formed at the same height as the upper surface of the cover ring 1123.

The flange 1122d is provided on the outer peripheral side of the outer circumferential portion 1122c. The upper surface of the flange 1122d is formed at a lower position than the upper surface of the outer circumferential portion 1122c. A inner circumferential portion of the cover ring 1123 is arranged on the flange 1122d. Accordingly, the flange 1122d of the under ring 1122 is restrained by the cover ring 1123, thereby preventing upward movement of the under ring 1122.

There is a gap in the radial direction between an outer circumferential wall (a cylindrical surface) of the inner circumferential portion 1122a of the under ring 1122 and an inner circumferential wall (a cylindrical surface) of the inner ring 1121. Additionally, there is a gap in the radial direction between an outer peripheral wall (a cylindrical surface) of the inner ring 1121 and an inner circumferential wall (a cylindrical surface) of the outer circumferential portion 1122c of the under ring 1122. Accordingly, rubbing of the inner ring 1121 and the under ring 1122 is prevented when the inner ring 1121 is moved up and down. Additionally, even when a temperature difference occurs between the inner ring 1121 and the under ring 1122, and a difference in thermal expansion between the inner ring 1121 and the under ring 1122 occurs, the inner ring 1121, the under ring 1122, or both are prevented from being damaged by the inner ring 1121 and the under ring 1122 coming into contact.

The cover ring 1123 is an annular member and is arranged so as to surround the edge ring 1120 (the under ring 1122). The cover ring 1123 is formed of an insulating material, such as SiO₂.

The insulator ring 1124 is an annular member and is disposed so as to surround the body 111 (the base 1110 and the electrostatic chuck 1111). The insulator ring 1124 is formed of an insulating material, such as SiO₂. The insulator ring 1124 supports the cover ring 1123.

### Alignment Structure of Under Ring 1122

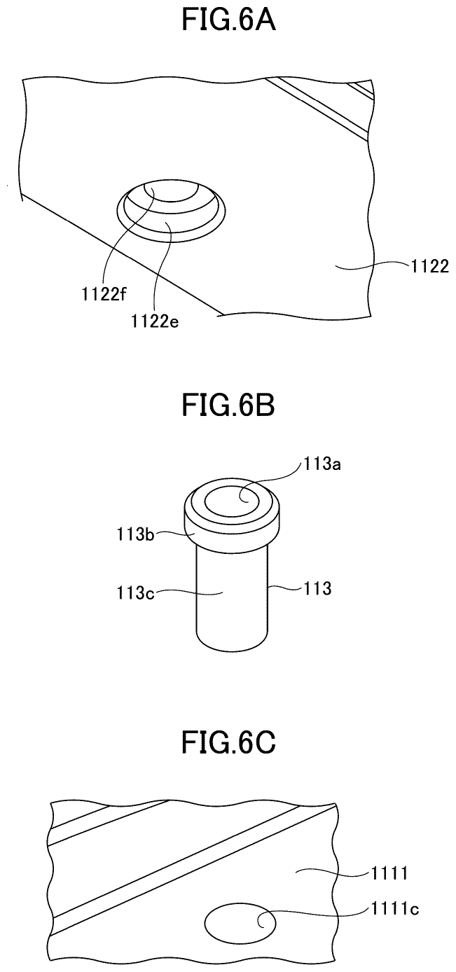

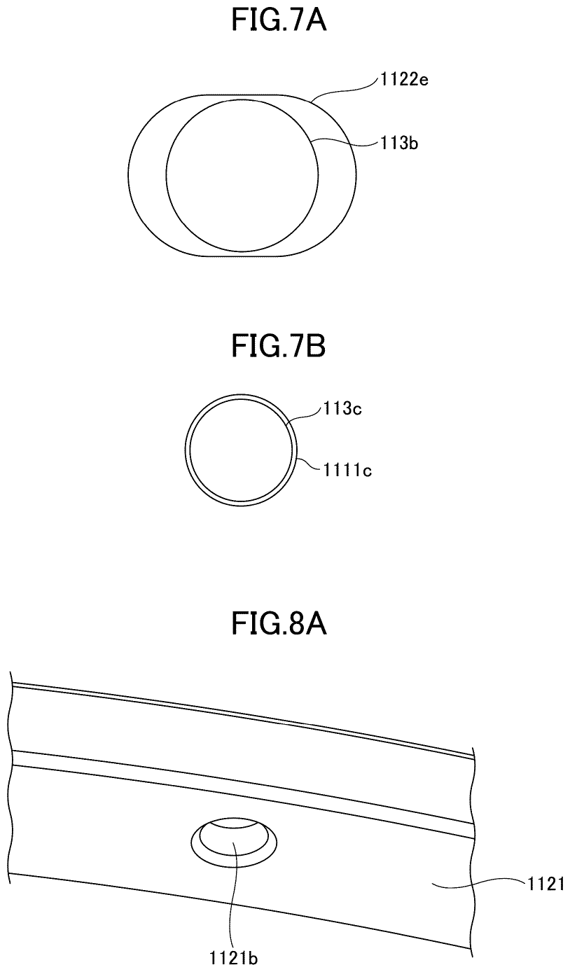

Next, a structure of the through-hole (1111c, 113a, and 1122f) through which the lift pin 115 is inserted and an alignment structure of the under ring 1122 with respect to the electrostatic chuck 1111 will be described with reference to FIGS. 6A to 6C and FIGS. 7A to 7B, as well as FIG. 3. FIGS. 6A to 6C are examples of perspective views for explaining the alignment structure of the under ring 1122. Specifically, FIG. 6A is an example of a perspective view of the under ring 1122 viewed from the lower surface side. FIG. 6B is an example of a perspective view of a cap 113. FIG. 6C is an example of a perspective view of the electrostatic chuck 1111 viewed from the upper surface side.

As illustrated in FIGS. 3 and 6C, the electrostatic chuck 1111 includes a through-hole (a first through-hole) 1111c through which the lift pin 115 is to be inserted. The through-hole 1111c penetrates from the upper surface to the lower surface of the electrostatic chuck 1111. Here, the through-hole 1111c communicates with the through-hole 1110c of the base 1110.

As illustrated in FIG. 3, the cap (a cylindrical member) 113 including a through-hole (a second through-hole) 113a is disposed in the through-hole 1111c. The cap 113 is formed of any one of sapphire, Al₂O₃, or SiC, for example. Additionally, the cap 113 is preferably formed of an insulating material in order to prevent abnormal discharge in the through-hole 113a (the through-hole 1111c). Additionally, the cap 113 is preferably formed of a material having corrosion resistance, plasma resistance and heat resistance.

As illustrated in FIG. 6B, the cap 113 is a cylindrical member and includes the through-hole 113a penetrating from the upper surface to the lower surface of the cap 113. The lift pin 115 is to be inserted into the through-hole 113a. Additionally, the cap 113 includes an upper head portion (a first head portion) 113b and a lower shaft portion (a first shaft portion) 113c. The shaft portion 113c has a circular outer shape viewed in plan view (in other words, viewed from the upper side, and in other words, viewed from a direction perpendicular to the ring support surface of the substrate support 11). The shaft portion 113c is a portion inserted into the through-hole 1111c of the electrostatic chuck 1111. The head portion 113b has a circular shape having a diameter larger than a diameter of the shaft portion 113c viewed in plan view. The head portion 113b is a portion disposed on the ring support surface (the annular region 111b) of the electrostatic chuck 1111 when the shaft portion 113c is inserted into the through-hole 1111c of the electrostatic chuck 1111.

As illustrated in FIGS. 3 and 6A, the under ring 1122 includes a counterbore (a first groove or a first counterbore) 1122e and a through-hole (a third through-hole) 1122f communicating with the counterbore 1122e. The counterbore 1122e is formed on the lower surface of the under ring 1122. When the under ring 1122 is placed on the ring support surface (the annular region 111b) of the electrostatic chuck 1111, the head portion 113b of the cap 113 is disposed in the counterbore 1122e. The through-hole 1122f communicates with the counterbore 1122e and penetrates the support 1122b of the under ring 1122 from the lower surface to the upper surface.

As illustrated in FIG. 3, the shaft portion 113c of the cap 113 is inserted into the through-hole 1111c of the electrostatic chuck 1111, and the head portion 113b of the cap 113 is disposed in the counterbore 1122e formed on the lower surface of the under ring 1122, so that the through-hole 113a of the cap 113 and the through-hole 1122f of the under ring 1122 communicate with each other. The lift pin 115 passes through the through-hole 113a of the cap 113 and the through-hole 1122f of the under ring 1122 to come in contact with the lower surface of the inner ring 1121. A notched portion 1121a is formed on the lower surface of the inner ring 1121 at a position where the inner ring 1121 is in contact with the lift pin 115. The notched portion 1121a is formed as an oblong hole whose longitudinal axis extends in the radial direction of the electrostatic chuck 1111. Additionally, the inner circumferential side of the notched portion 1121a is formed up to the inner circumferential wall of the inner ring 1121.

FIGS. 7A to 7B are examples of schematic views for explaining the alignment structure of the under ring 1122. Specifically, FIG. 7A is a schematic view of the shape of the counterbore 1122e of the under ring 1122 and the shape of the head portion 113b of the cap 113 disposed in the counterbore 1122e viewed in plan view. FIG. 7B is a schematic view of the shape of the through-hole 1111c of the electrostatic chuck 1111 and the shape of the shaft portion 113c of the cap 113 disposed in the through-hole 1111c viewed in plan view.

As illustrated in FIG. 7B, the shape (the outer peripheral shape) of the shaft portion 113c of the cap 113 is a circular shape. Additionally, the shape (the inner peripheral shape) of the through-hole 1111c of the electrostatic chuck 1111 is a circular shape. Additionally, the inner diameter of the shape of the through-hole 1111c is formed slightly larger than the outer diameter of the shape of the shaft portion 113c so that the shaft portion 113c can be inserted into the through-hole 1111c. By inserting the shaft portion 113c of the cap 113 into the through-hole 1111c of the electrostatic chuck 1111, the cap 113 is disposed such that the axis of the through-hole 1111c is aligned with the axis of the cap 113. That is, the cap 113 is aligned with respect to the electrostatic chuck 1111.

As illustrated in FIG. 7A, the shape (the outer circumferential shape) of the head portion 113b of the cap 113 is a circular shape. In contrast, the shape (the inner circumferential shape) of the counterbore 1122e of the under ring 1122 is an oblong hole shape (a slot hole shape) whose longitudinal axis extends in the radial direction of the electrostatic chuck 1111. Additionally, the width of the counterbore 1122e in the transverse direction is formed slightly larger than the outer diameter of the shape of the head portion 113b so that the head portion 113b can be disposed in the counterbore 1122e.

Additionally, as illustrated in FIG. 5, the alignment structures of the under ring 1122 each including the through-hole 1111c, the cap 113, and the counterbore 1122e are provided at three positions at equal intervals in the circumferential direction. In each of the three alignment structures of the under ring 1122 provided at the positions S1, the outer circumferential surface of the head portion 113b of the cap 113 is in contact with the inner circumferential surface of the counterbore 1122e of the under ring 1122. With this configuration, the under ring 1122 is aligned at three points with respect to the electrostatic chuck 1111. Accordingly, the position of the under ring 1122 (the edge ring 1120) can be adjusted with respect to the body 111 including the electrostatic chuck 1111. That is, the center of the body 111 having a circular shape in plan view is aligned with the center of the under ring 1122 having an annular shape in plan view.

Additionally, the counterbore 1122e has an oblong hole whose longitudinal axis extends in the radial direction of the electrostatic chuck 1111, so that a difference in thermal expansion between the electrostatic chuck 1111 and the under ring 1122 can be accommodated.

### Alignment Structure of Inner Ring 1121

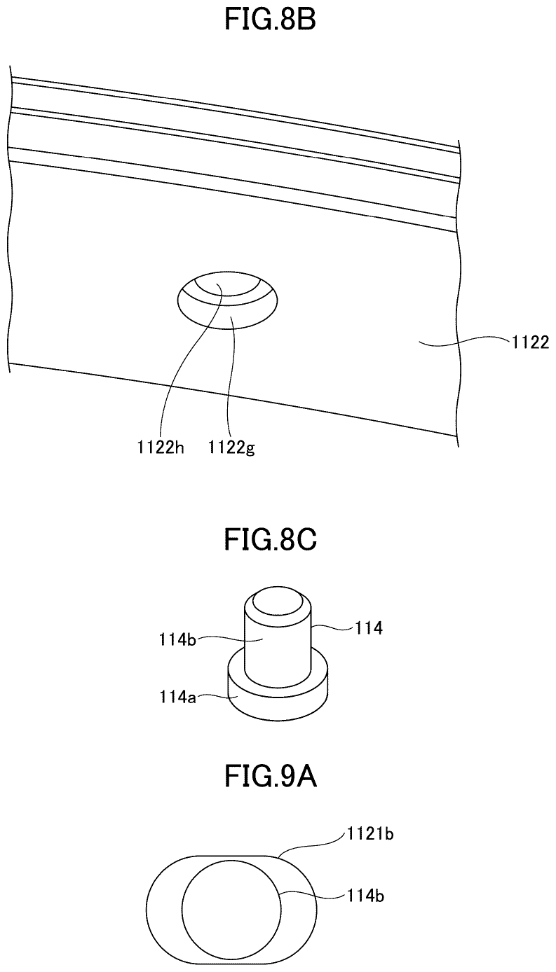

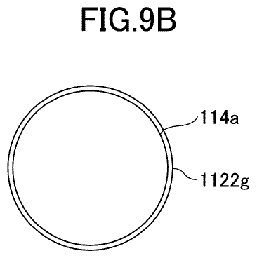

Next, an alignment structure of the inner ring 1121 with respect to the under ring 1122 will be described with reference to FIGS. 8A to 8C and FIGS. 9A to 9B, as well as FIG. 4. FIGS. 8A to 8C are examples of perspective views for explaining the alignment structure of the inner ring 1121. Specifically, FIG. 8A is an example of a perspective view of the inner ring 1121 viewed from the lower surface side. FIG. 8B is an example of a perspective view of the under ring 1122 viewed from the lower surface side. FIG. 8C is an example of a perspective view of a guide pin 114.

As illustrated in FIGS. 4 and 8A, the lower surface of the inner ring 1121 includes a groove (a second groove) 1121b.

As illustrated in FIGS. 4 and 8B, the under ring 1122 includes a counterbore (a second counterbore) 1122g and a through-hole (a fourth through-hole) 1122h communicating with the counterbore 1122g. The counterbore 1122g is formed on the lower surface of the under ring 1122. A head portion 114a of the guide pin 114 is disposed in the counterbore 1122g. The through-hole 1122h communicates with the counterbore 1122g and penetrates the support 1122b of the under ring 1122 from the lower surface to the upper surface.

As illustrated in FIG. 4, the guide pin 114 is disposed extending from the counterbore 1122g and the through-hole 1122h of the under ring 1122 to the groove 1121b of the inner ring 1121. The guide pin 114 is formed of any one of sapphire, Al₂O₃, or SiC, for example. Additionally, the guide pin 114 is preferably formed of an insulating material in order to prevent abnormal discharge. Additionally, the guide pin 114 is preferably formed of a material having corrosion resistance, plasma resistance, and heat resistance.

As illustrated in FIG. 8C, the guide pin 114 is a shaft member and includes the head portion (a second head portion) 114a on the lower side and a shaft portion (a second shaft portion) 114b on the upper side. The shaft portion 114b has a circular outer shape viewed in plan view. The shaft portion 114b passes through the through-hole 1122h of the under ring 1122 and is inserted into the groove 1121b of the inner ring 1121. The head portion 114a has a circular outer shape having a diameter larger than a diameter of the shaft portion 114b viewed in plan view. The head portion 114a is disposed in the counterbore 1122g of the under ring 1122.

FIGS. 9A and 9B are examples of schematic views for explaining the alignment structure of the inner ring 1121. Specifically, FIG. 9A is a schematic view of the shape of the groove 1121b of the inner ring 1121 and the shape of the shaft portion 114b of the guide pin 114 disposed in the groove 1121b viewed in plan view. FIG. 9B is a schematic view of the shape of the counterbore 1122g of the under ring 1122 and the shape of the head portion 114a of the guide pin 114 disposed in the counterbore 1122g viewed in plan view.

As illustrated in FIG. 9B, the shape (the outer circumferential shape) of the head portion 114a of the guide pin 114 is a circular shape. Additionally, the shape (the inner circumferential shape) of the counterbore 1122g of the under ring 1122 is a circular shape. Additionally, the inner diameter of the counterbore 1122g is formed slightly larger than the outer diameter of the head portion 114a so that the head portion 114a of the guide pin 114 can be inserted. By inserting the head portion 114a of the guide pin 114 into the counterbore 1122g of the under ring 1122, the axis of the counterbore 1122g is aligned with the axis of the guide pin 114. That is, the guide pin 114 is aligned with respect to the under ring 1122.

As illustrated in FIG. 9A, the shape (the outer circumferential shape) of the shaft portion 114b of the guide pin 114 is a circular shape. In contrast, the shape (the inner circumferential shape) of the groove 1121b of the inner ring 1121 is an oblong hole shape (a slot hole shape) whose longitudinal axis extends in the radial direction of the electrostatic chuck 1111. Additionally, the width of the groove 1121b in the transverse direction is formed slightly larger than the outer diameter of the shape of the shaft portion 114b so that the shaft portion 114b can be disposed in the groove 1121b.

Additionally, as illustrated in FIG. 5, the alignment structures of the inner ring 1121 including the guide pin 114, the counterbore 1122g and the through-hole 1122h of the under ring 1122, and the groove 1121b of the inner ring 1121 are provided at three positions at equal intervals in the circumferential direction. In each of the three alignment structures of the inner ring 1121 provided at the positions S2, the outer circumferential surface of the shaft portion 114b of the guide pin 114 comes in contact with the inner circumferential surface of the groove 1121b of the inner ring 1121. With this configuration, the inner ring 1121 is aligned at three points with respect to the under ring 1122. Additionally, the position of the inner ring 1121 can be adjusted with respect to the body 111 including the electrostatic chuck 1111 via the aligned under ring 1122. That is, the center of the under ring 1122 having an annular shape viewed in plan view is aligned with the center of the inner ring 1121 having an annular shape viewed in plan view. Additionally, the center of the body 111 having a circular shape viewed in plan view is aligned with the center of the inner ring 1121 having an annular shape viewed in plan view.

Additionally, the groove 1121b has an oblong hole shape whose longitudinal axis extends in the radial direction of the electrostatic chuck 1111, so that a difference in thermal expansion between the inner ring 1121 and the under ring 1122 can be accommodated.

As described above, according to the substrate support 11 of the first embodiment, misalignment due to thermal expansion of the edge ring 1120 (the inner ring 1121 and the under ring 1122) by heat that is input during substrate processing can be suppressed. Additionally, by suppressing misalignment of the edge ring 1120, the stability of the substrate processing is improved.

Additionally, when there is a potential difference between the inner ring 1121 lifted by the lift pin 115 and the under ring 1122, there is a possibility that abnormal discharge may occur due to the contact of the inner ring 1121 with the under ring 1122. According to the substrate support 11 of the first embodiment, the occurrence of abnormal discharge can be suppressed by suppressing misalignment of the edge ring 1120.

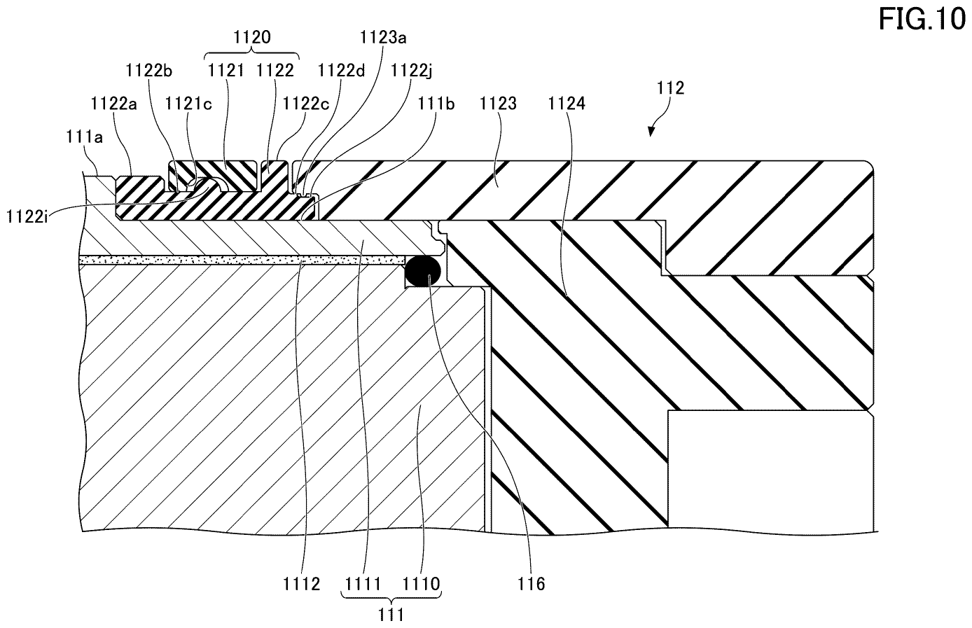

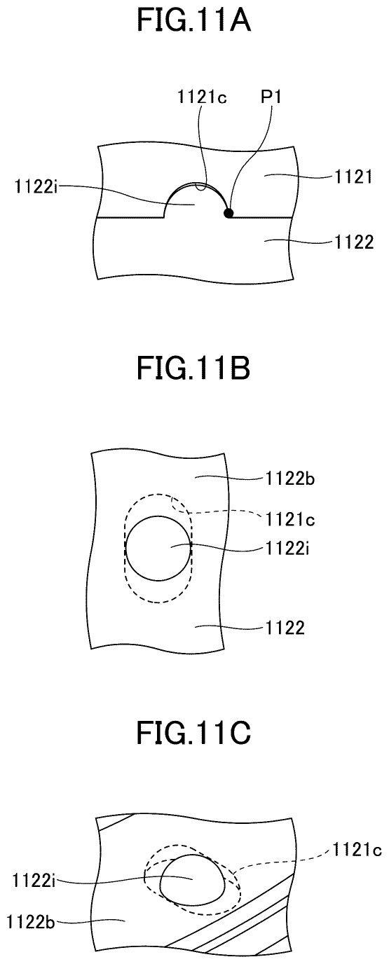

Next, a substrate support 11 according to a second embodiment will be further described with reference to FIGS. 10 to 11D.

Here, in the substrate support 11 according to the second embodiment, the alignment structure of the under ring 1122 has the same structure as the alignment structure of the under ring 1122 in the substrate support 11 according to the first embodiment (see FIGS. 3, 6, and 7). Additionally, the substrate support 11 according to the second embodiment has a different alignment structure of the inner ring 1121. Thus, the alignment structure of the inner ring 1121 in the substrate support 11 according to the second embodiment will be described below, and the description overlapping with that of the substrate support 11 according to the first embodiment will be omitted.

FIG. 10 is an example of an enlarged cross-sectional view of the substrate support 11 according to the second embodiment. FIGS. 11A to 11D are examples of diagrams for explaining the alignment structure of the inner ring 1121. Here, FIG. 10 is a cross-sectional view of the substrate support 11 taken by cutting the substrate support 11 in the radial direction, and the left side of the drawing corresponds to the center side of the substrate support 11, and the right side of the drawing corresponds to the outer periphery side of the substrate support 11. FIG. 10 is a cross-sectional view at a position S2 (a position indicated by a solid circle in FIG. 5) where the alignment structure of the inner ring 1121 is provided. Specifically, FIG. 11A is a schematic cross-sectional view of the inner ring 1121 and the under ring 1122 taken by cutting the inner ring 1121 and the under ring 1122 in the radial direction. FIG. 11B is a diagram of the under ring 1122 viewed from above. FIG. 11C is a perspective view of the under ring 1122 viewed from above. FIG. 11D is a perspective view of the inner ring 1121 viewed from below.

As illustrated in FIG. 10, a convex portion (a first convex portion) 1122i is formed on the upper surface of the support 1122b of the under ring 1122. Additionally, a groove (a third groove) 1121c is formed on the lower surface of the inner ring 1121. The lower surface of the inner ring 1121 comes in contact with the upper surface of the support 1122b of the under ring 1122. The convex portion 1122i is disposed in the groove 1121c.

As illustrated in FIGS. 11A to 11C, the convex portion 1122i has a spherical shape.

As illustrated in FIG. 11A, the groove 1121c has a circular arc shape in cross section viewed in the radial direction. The radius of curvature of the circular arc shape of the groove 1121c is formed larger than the radius of curvature of the spherical surface of the convex portion 1122i. Additionally, as illustrated in FIGS. 11B to 11D, the groove 1121c is formed as an oblong hole whose longitudinal axis extends in the radial direction of the electrostatic chuck 1111.

Here, in the alignment structure of the inner ring 1121 provided at the position S2, the convex portion 1122i of the under ring 1122 comes in contact with the groove 1121c of the inner ring 1121 at one point. FIG. 11A illustrates an example of the contact point P1. As illustrated in FIG. 5, the alignment structures of the inner ring 1121 including the convex portion 1122i and the groove 1121c are provided at three positions at equal intervals in the circumferential direction. With this configuration, the inner ring 1121 is aligned at three points with respect to the under ring 1122. Additionally, the position of the inner ring 1121 can be adjusted with respect to the body 111 including the electrostatic chuck 1111 via the aligned under ring 1122. That is, the center of the under ring 1122 having an annular shape viewed in plan view is aligned with the center of the inner ring 1121 having an annular shape viewed in plan view. Additionally, the center of the body 111 having a circular shape viewed in plan view is aligned with the center of the inner ring 1121 having an annular shape viewed in plan view.

Additionally, the groove 1121c has an oblong hole shape whose longitudinal axis extends in the radial direction of the electrostatic chuck 1111, so that a thermal expansion difference between the inner ring 1121 and the under ring 1122 can be accommodated.

As described above, according to the substrate support 11 of the second embodiment, misalignment due to thermal expansion of the edge ring 1120 (the inner ring 1121 and the under ring 1122) caused by heat that is input during substrate processing can be suppressed. Additionally, by suppressing misalignment of the edge ring 1120, the stability of the substrate processing is improved.

Additionally, when there is a potential difference between the inner ring 1121 lifted by the lift pin 115 and the under ring 1122, there is a possibility that abnormal discharge may occur due to the contact of the inner ring 1121 with the under ring 1122. According to the substrate support 11 of the second embodiment, the occurrence of abnormal discharge can be suppressed by suppressing misalignment of the edge ring 1120.

Additionally, when the inner ring 1121 lifted by the lift pin 115 is lowered and placed on the support 1122b of the under ring 1122, the convex portion 1122i of the under ring 1122 enters the groove 1121c of the inner ring 1121, and the convex portion 1122i comes in contact with the groove 1121c, thereby adjusting the center position. Accordingly, even when the inner ring 1121 lifted by the lift pin 115 is misaligned due to thermal expansion or the like, the center position can be adjusted by lowering the inner ring 1121 and placing it on the support 1122b of the under ring 1122.

Additionally, the convex portion 1122i and the groove 1121c are in contact with each other at one contact point P1. Accordingly, the lower surface of the inner ring 1121 and the upper surface of the support 1122b of the under ring 1122 can be reliably brought into contact with each other.

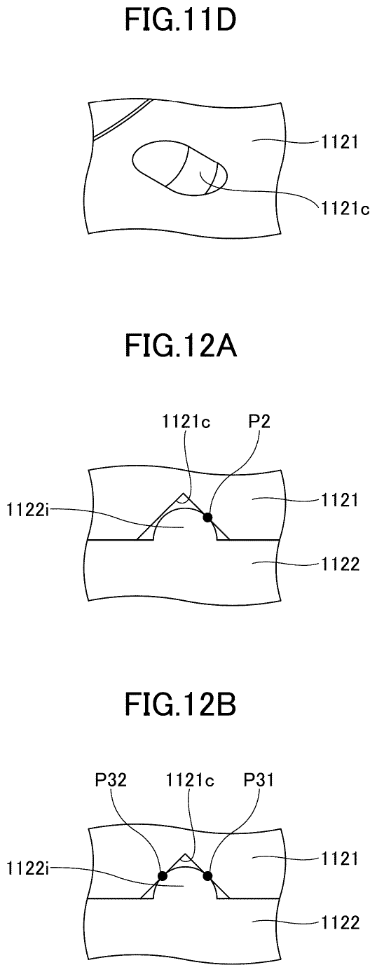

Although the configuration, in which the groove 1121c formed in the inner ring 1121 has an arc shape in cross section viewed in the radial direction as illustrated in FIG. 11A, has been described, the embodiment is not limited to this. FIGS. 12A to 12B are other examples of diagrams for explaining the alignment structure of the inner ring 1121.

As illustrated in FIG. 12A, the groove 1121c may have an inverted V-shape in cross section viewed in the radial direction. Additionally, the convex portion 1122i and the groove 1121c are configured to be in contact with each other at one contact point P2. Accordingly, the lower surface of the inner ring 1121 and the upper surface of the support 1122b of the under ring 1122 can be reliably brought into contact with each other.

As illustrated in FIG. 12B, the groove 1121c may have an inverted V-shape in cross section viewed in the radial direction, and the convex portion 1122i and the groove 1121c may be in contact with each other at two contact points P31 and P32. That is, the three convex portions 1122i formed on the under ring 1122 and the three grooves 1121c formed on the inner ring 1121 are in contact with each other at a total of six contact points. This forms a kinematic coupling, thereby further improving the accuracy of aligning the inner ring 1121 with respect to the under ring 1122.

Although the illustration is omitted, the groove 1121c may have an arc shape in cross section viewed in the radial direction, and the convex portion 1122i and the groove 1121c may be in contact with each other at two contact points. That is, the three convex portions 1122i formed on the under ring 1122 and the three grooves 1121c formed on the inner ring 1121 are in contact with each other at a total of six contact points. This forms a kinematic coupling, thereby further improving the accuracy of aligning the inner ring 1121 with respect to the under ring 1122.

### Alignment Structure of Cover Ring 1123

Additionally, as illustrated in FIG. 10, the substrate support 11 according to the second embodiment has an alignment structure of the cover ring 1123 for aligning the cover ring 1123 with respect to the under ring 1122. The alignment structure of the cover ring 1123 includes a groove (a fourth groove) 1122j provided on the upper surface of the flange 1122d of the under ring 1122, and a convex portion (a second convex portion) 1123a provided on the lower surface of the cover ring 1123 on the inner circumferential side (a portion disposed on the flange 1122d). The convex portion 1123a has a spherical shape, similar to the convex portion 1122i. Similar to the groove 1121c, the groove 1122j has an arc shape or an inverted V-shape in cross section viewed in the radial direction of the electrostatic chuck 1111, and is an oblong hole whose longitudinal axis extends in the radial direction of the electrostatic chuck 1111. Here, the convex portion may be provided on the upper surface of the flange 1122d of the under ring 1122, and the groove may be provided on the lower surface of the cover ring 1123 on the inner circumferential side.

Additionally, the alignment structure of the cover ring 1123 illustrated in FIG. 10 may be applied to the substrate support 11 according to the first embodiment illustrated in FIG. 3, for example.

The embodiments disclosed above include, for example, the following aspects.

(Clause 1) A substrate processing apparatus including:
an electrostatic chuck having a substrate support surface and a ring support surface, the ring support surface including a first through-hole through which a lift pin is to be inserted into the ring support surface;
an edge ring supported by the ring support surface; and
a cylindrical member inserted into the first through-hole of the electrostatic chuck, the cylindrical member including a second through-hole,
wherein the cylindrical member includes:
   a first shaft portion inserted into the first through-hole of the electrostatic chuck; and
   a first head portion arranged on the ring support surface of the electrostatic chuck when the first shaft portion is inserted into the first through-hole of the electrostatic chuck, and
wherein the edge ring includes a first groove in which the first head portion is to be arranged, the first groove being provided on a lower surface of the edge ring.

(Clause 2) The substrate processing apparatus as described in Clause 1, wherein the first groove is an oblong hole having a longitudinal axis extending in a radial direction of the electrostatic chuck.

(Clause 3) The substrate processing apparatus as described in Clause 2 or 3, wherein the first head portion has a diameter larger than a diameter of the first shaft portion.

(Clause 4) The substrate processing apparatus as described in any one of Clauses 1 to 3, including three cylindrical members including the cylindrical member,
wherein the ring support surface includes three first through-holes including the first through-hole and the edge ring includes three first grooves including the first groove, and
wherein the three first through-holes, the three cylindrical members, and the three first grooves are provided in circumferential direction.

(Clause 5) The substrate processing apparatus as described in any one of Clauses 1 to 4,
wherein the edge ring includes:
   an under ring supported by the ring support surface; and
   an inner ring disposed on the under ring, and
wherein the under ring includes:
   a first counterbore as the first groove; and
   a third through-hole communicating with the first counterbore, penetrating from a lower surface to an upper surface of the under ring, and communicating with the second through-hole of the cylindrical member such that the lift pin is insertable.

(Clause 6) The substrate processing apparatus as described in Clause 5, further including a guide pin including a second shaft portion and a second head portion having a diameter larger than a diameter of the second shaft portion,
wherein the under ring includes:
   a second counterbore provided on the lower surface of the under ring, the second head portion being arranged in the second counterbore; and
   a fourth through-hole communicating with the second counterbore and penetrating from the lower surface to the upper surface of the under ring, the second shaft portion being inserted through the fourth through-hole, and
wherein the inner ring includes a second groove provided on a lower surface of the inner ring, and the second shaft portion protrudes from the under ring and the second shaft portion is arranged in the second groove.

(Clause 7) The substrate processing apparatus as described in Clause 6, wherein the second groove is an oblong hole having a longitudinal axis extending in a radial direction of the electrostatic chuck.

(Clause 8) The substrate processing apparatus as described in Clause 6 or 7, including three guide pins including the guide pin,
wherein the under ring includes three second counterbores including the second counterbore, and three fourth through-holes including the fourth through-hole,
wherein the inner ring includes three second grooves including the second groove, and
wherein the three second counterbores, the three fourth through-holes, and the three second grooves are provided in a circumferential direction.

(Clause 9) The substrate processing apparatus as described in Clause 6,
wherein the under ring includes a first convex portion, and
wherein the inner ring includes a third groove provided on a lower surface of the inner ring, the first convex portion of the under ring being arranged in the third groove.

(Clause 10) The substrate processing apparatus as described in Clause 9,
wherein the first convex portion has a spherical shape, and
wherein the third groove has an arc shape in a cross section viewed in a radial direction of the electrostatic chuck and is an oblong hole having a longitudinal axis extending in the radial direction of the electrostatic chuck.

(Clause 11) The substrate processing apparatus as described in Clause 9,
wherein the first convex portion has a spherical shape, and
wherein the third groove has an inverted V-shape in a cross section viewed in a radial direction of the electrostatic chuck and is an oblong hole having a longitudinal axis extending in the radial direction of the electrostatic chuck.

(Clause 12) The substrate processing apparatus as described in Clause 10 or 11, wherein the first convex portion is in contact with the third groove at one point.

(Clause 13) The substrate processing apparatus as described in Clause 10 or 11, wherein the first convex portion is in contact with the third groove at two points.

(Clause 14) The substrate processing apparatus as described in any one of Clauses 9 to 13,
wherein the under ring includes three first convex portions including the first convex portion and the inner ring includes three third grooves including the third groove, and
wherein the three first convex portions and the three third grooves are provided in a circumferential direction.

(Clause 15) The substrate processing apparatus as described in any one of Clauses 9 to 14, further including a cover ring surrounding the edge ring,
wherein one of the under ring or the cover ring includes a second convex portion, and another one of the under ring or the cover ring includes a fourth groove, the second convex portion being arranged in the fourth groove.

(Clause 16) A method for processing a substrate, comprising:
supporting an edge ring on a ring support surface of an electrostatic chuck, the ring support surface including a first through-hole;
aligning the edge ring with respect to the electrostatic chuck using a cylindrical member inserted into the first through-hole, the cylindrical member including a first shaft portion inserted into the first through-hole and a first head portion arranged in a first groove provided on a lower surface of the edge ring;
supporting a substrate on a substrate support surface of the electrostatic chuck; and
processing the substrate in a plasma processing space.

(Clause 17) The method as claimed in Clause 16, further comprising:
raising a lift pin through the first through-hole and a second through-hole of the cylindrical member to lift an inner ring of the edge ring; and
adjusting a height of the inner ring to compensate for wear of the inner ring.

(Clause 18) The method as claimed in Clause 16, wherein the aligning includes:
accommodating a difference in thermal expansion between the electrostatic chuck and the edge ring by the first groove having an oblong hole shape having a longitudinal axis extending in a radial direction of the electrostatic chuck.

(Clause 19) A non-transitory computer-readable medium storing a program that, when executed by a processor of a controller, causes a substrate processing apparatus to perform operations comprising:
controlling a height adjusting mechanism to raise a lift pin through a first through-hole in a ring support surface of an electrostatic chuck and through a second through-hole of a cylindrical member inserted into the first through-hole, the cylindrical member including a first shaft portion inserted into the first through-hole and a first head portion arranged in a first groove on a lower surface of an edge ring supported by the ring support surface;
lifting an inner ring of the edge ring from an under ring of the edge ring using the lift pin; and
adjusting a height of the inner ring in accordance with an amount of wear of the inner ring.

(Clause 20) The non-transitory computer-readable medium as claimed in Clause 19, wherein the operations further comprise:
lowering the lift pin to place the inner ring on a support of the under ring; and
aligning the inner ring with respect to the under ring by a convex portion of the under ring entering a third groove of the inner ring.

Embodiments of the plasma processing system have been described above, but the present disclosure is not limited to the above embodiments, and various modifications and improvements can be made within the scope of the present disclosure described in the appended claims.

According to one aspect, a substrate processing apparatus for aligning an edge ring can be provided. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

What is claimed is:

1. A substrate processing apparatus comprising:
an electrostatic chuck having a substrate support surface and a ring support surface, the ring support surface including a first through-hole through which a lift pin is to be inserted into the ring support surface;
an edge ring supported by the ring support surface; and
a cylindrical member inserted into the first through-hole of the electrostatic chuck, the cylindrical member including a second through-hole,
wherein the cylindrical member includes:
a first shaft portion inserted into the first through-hole of the electrostatic chuck; and
a first head portion arranged on the ring support surface of the electrostatic chuck when the first shaft portion is inserted into the first through-hole of the electrostatic chuck, and
wherein the edge ring includes a first groove in which the first head portion is to be arranged, the first groove being provided on a lower surface of the edge ring.

2. The substrate processing apparatus as claimed in claim 1, wherein the first groove is an oblong hole having a longitudinal axis extending in a radial direction of the electrostatic chuck.

3. The substrate processing apparatus as claimed in claim 1, wherein the first head portion has a diameter larger than a diameter of the first shaft portion.

4. The substrate processing apparatus as claimed in claim 1, comprising three cylindrical members including the cylindrical member,
wherein the ring support surface includes three first through-holes including the first through-hole and the edge ring includes three first grooves including the first groove, and
wherein the three first through-holes, the three cylindrical members, and the three first grooves are provided in circumferential direction.

5. The substrate processing apparatus as claimed in claim 1,
wherein the edge ring includes:
an under ring supported by the ring support surface; and
an inner ring disposed on the under ring, and
wherein the under ring includes:
a first counterbore as the first groove; and
a third through-hole communicating with the first counterbore, penetrating from a lower surface to an upper surface of the under ring, and communicating with the second through-hole of the cylindrical member such that the lift pin is insertable.

6. The substrate processing apparatus as claimed in claim 5, further comprising a guide pin including a second shaft portion and a second head portion having a diameter larger than a diameter of the second shaft portion,
wherein the under ring includes:
a second counterbore provided on the lower surface of the under ring, the second head portion being arranged in the second counterbore; and
a fourth through-hole communicating with the second counterbore and penetrating from the lower surface to the upper surface of the under ring, the second shaft portion being inserted through the fourth through-hole, and
wherein the inner ring includes a second groove provided on a lower surface of the inner ring, and
the second shaft portion protrudes from the under ring and the second shaft portion is arranged in the second groove.

7. The substrate processing apparatus as claimed in claim 6, wherein the second groove is an oblong hole having a longitudinal axis extending in a radial direction of the electrostatic chuck.

8. The substrate processing apparatus as claimed in claim 6, comprising three guide pins including the guide pin,
wherein the under ring includes three second counterbores including the second counterbore, and three fourth through-holes including the fourth through-hole,
wherein the inner ring includes three second grooves including the second groove, and
wherein the three second counterbores, the three fourth through-holes, and the three second grooves are provided in a circumferential direction.

9. The substrate processing apparatus as claimed in claim 6,
wherein the under ring includes a first convex portion, and
wherein the inner ring includes a third groove provided on a lower surface of the inner ring, the first convex portion of the under ring being arranged in the third groove.

10. The substrate processing apparatus as claimed in claim 9,
wherein the first convex portion has a spherical shape, and
wherein the third groove has an arc shape in a cross section viewed in a radial direction of the electrostatic chuck and is an oblong hole having a longitudinal axis extending in the radial direction of the electrostatic chuck.

11. The substrate processing apparatus as claimed in claim 9,
wherein the first convex portion has a spherical shape, and
wherein the third groove has an inverted V-shape in a cross section viewed in a radial direction of the electrostatic chuck and is an oblong hole having a longitudinal axis extending in the radial direction of the electrostatic chuck.

12. The substrate processing apparatus as claimed in claim 10, wherein the first convex portion is in contact with the third groove at one point.

13. The substrate processing apparatus as claimed in claim 10, wherein the first convex portion is in contact with the third groove at two points.

14. The substrate processing apparatus as claimed in claim 9,
wherein the under ring includes three first convex portions including the first convex portion and the inner ring includes three third grooves including the third groove, and
wherein the three first convex portions and the three third grooves are provided in a circumferential direction.

15. The substrate processing apparatus as claimed in claim 9, further comprising a cover ring surrounding the edge ring,
wherein one of the under ring or the cover ring includes a second convex portion, and another one of the under ring or the cover ring includes a fourth groove, the second convex portion being arranged in the fourth groove.

16. A method for processing a substrate, comprising:
supporting an edge ring on a ring support surface of an electrostatic chuck, the ring support surface including a first through-hole;
aligning the edge ring with respect to the electrostatic chuck using a cylindrical member inserted into the first through-hole, the cylindrical member including a first shaft portion inserted into the first through-hole and a first head portion arranged in a first groove provided on a lower surface of the edge ring;
supporting a substrate on a substrate support surface of the electrostatic chuck; and
processing the substrate in a plasma processing space.

17. The method as claimed in claim 16, further comprising:
raising a lift pin through the first through-hole and a second through-hole of the cylindrical member to lift an inner ring of the edge ring; and
adjusting a height of the inner ring to compensate for wear of the inner ring.

18. The method as claimed in claim 16, wherein the aligning includes:
accommodating a difference in thermal expansion between the electrostatic chuck and the edge ring by the first groove having an oblong hole shape having a longitudinal axis extending in a radial direction of the electrostatic chuck.

19. A non-transitory computer-readable medium storing a program that, when executed by a processor of a controller, causes a substrate processing apparatus to perform operations comprising:
controlling a height adjusting mechanism to raise a lift pin through a first through-hole in a ring support surface of an electrostatic chuck and through a second through-hole of a cylindrical member inserted into the first through-hole, the cylindrical member including a first shaft portion inserted into the first through-hole and a first head portion arranged in a first groove on a lower surface of an edge ring supported by the ring support surface;
lifting an inner ring of the edge ring from an under ring of the edge ring using the lift pin; and
adjusting a height of the inner ring in accordance with an amount of wear of the inner ring.

20. The non-transitory computer-readable medium as claimed in claim 19, wherein the operations further comprise:
lowering the lift pin to place the inner ring on a support of the under ring; and
aligning the inner ring with respect to the under ring by a convex portion of the under ring entering a third groove of the inner ring.
